(19) United States
(12) Patent Application Publication
(10) Pub. No.: US 2013/0260564 A1
(43) Pub. Date: Oct. 3, 2013

(54) INSENSITIVE DRY REMOVAL PROCESS FOR SEMICONDUCTOR INTEGRATION

(71) Applicant: APPLIED MATERIALS, INC., Santa Clara, CA (US)

(72) Inventors: Kedar Sapre, San Jose, CA (US); Rossella Mininni, Mountain View, CA (US); Jing Tang, San Jose, CA (US)

(21) Appl. No.: 13/624,693

(22) Filed: Sep. 21, 2012

Related U.S. Application Data
(60) Provisional application No. 61/539,270, filed on Sep. 26, 2011.

(51) Int. Cl. H01L 29/40

(52) U.S. Cl. CPC H01L 29/401
USPC 438/703

(57) ABSTRACT

Methods of depositing and etching dielectric layers from a surface of a semiconductor substrate are disclosed. The methods may include depositing a first dielectric layer having a first wet etch rate in aqueous HF. The methods also may include depositing a second dielectric layer that may be initially flowable following deposition, and the second dielectric layer may have a second wet etch rate in aqueous HF that is higher than the first wet etch rate. The methods may further include etching the first and second dielectric layers with an etchant gas mixture, where the first and second dielectric layers have a ratio of etch rates that is closer to one than the ratio of the second wet etch rate to the first wet etch rate in aqueous HF.

### CROSS-REFERENCES TO RELATED APPLICATIONS

This application claims the benefit of U.S. Provisional Application No. 61/539,270, filed Sep. 26, 2011, entitled “Insensitive Dry Removal Process for Semiconductor Integration.” The entire disclosure of which is incorporated herein.

### BACKGROUND

Semiconductor processing often includes many distinct manufacturing steps. With the current state of technology, circuit components are routinely formed on nanometer scales, and sensitive manufacturing techniques are required. For instance, in replacement metal gate (“RMG” or “gate last”) processing, a sacrificial material located within a trench or within another feature on a semiconductor substrate may need to be removed in the presence of a non-sacrificial material on the substrate. Etching techniques used to remove the first material may expose both the first and second material to the etchant, which may remove both the sacrificial and non-sacrificial material. If too much or all of the non-sacrificial material is removed before the sacrificial material is removed, the substrate may be ruined.

Because gate last processing may include sacrificial material removal after non-sacrificial films have been deposited, delicate and controlled etching techniques are needed. Although a variety of etch techniques are available, few provide removal that accounts both for the type and quality of the films that may reside on the semiconductor substrate. For example, wet removal utilizing hydrogen-fluoride solutions is available for many types of film or oxide removal. However, these solutions are sensitive to the density or quality of the materials that have been deposited, and may remove too much of a non-sacrificial material. In some instances, a wet etch will remove a lower quality film up to forty times faster than a higher quality film. If the lower quality film is non-sacrificial, the wet etch removal may be incapable of removing the sacrificial layer before removing too much, if not all, of the non-sacrificial layer.

Thus, there is a continued need for techniques and products for removing sacrificial films in the presence of non-sacrificial films. These and other needs are addressed by the present technology.

### BRIEF SUMMARY

The present technology provides methods of removing dielectric materials from the surface of a semiconductor substrate that are substantially insensitive to the quality of the material being removed. Sacrificial films of a higher film quality may be removed in the presence of non-sacrificial films of a lower film quality by using a combination of dry etchant gases that etch oxides at substantially similar rates.

Methods of depositing and etching dielectric layers from a surface of a semiconductor substrate are disclosed. The methods may include depositing a first dielectric layer having a first wet etch rate in aqueous HF. The methods also may include depositing a second dielectric layer that may be initially flowable following deposition, and the second dielectric layer may have a second wet etch rate in aqueous HF that is higher than the first wet etch rate. The methods may further include etching the first and second dielectric layers with an etchant gas mixture, where the first and second dielectric layers have a ratio of etch rates that is closer to one than the ratio of the second wet etch rate to the first wet etch rate in aqueous HF.

Embodiments of the technology also include methods of removing a dielectric material on a surface of a semiconductor substrate. The methods may be utilized for gate last processing and may include depositing a first dielectric material on the substrate to produce a dielectric layer of a first quality that has a first wet etch rate in aqueous HF. A second dielectric material may also be deposited, and the second dielectric material may be initially flowable following deposition. The second dielectric material may be cured to produce a second dielectric layer of a second quality that has a second wet etch rate in aqueous HF that is greater than the first wet etch rate. The methods may also include etching the first and second dielectric layers with a dry etchant gas mixture, where the first and second dielectric layers have a ratio of etch rates with the dry etchant gas mixture that is closer to one than the ratio of the second wet etch rate to the first wet etch rate in aqueous HF.

Additional embodiments and features are set forth in part in the description that follows, and will become apparent to those skilled in the art upon examination of the specification and/or may be learned by the practice of the disclosed methods. The features and advantages of the disclosed processes and methods may be realized and attained by means of the instrumentalities, combinations, and/or methods described in the specification.

### BRIEF DESCRIPTION OF THE DRAWINGS

FIG. 1 shows cross-sectional views of a substrate on which a dummy gate removal process has been performed.

FIG. 2 shows a flowchart of an etch process according to disclosed methods.

FIG. 3 shows a flowchart of an etch process according to disclosed methods.

FIG. 4 shows a cross-sectional view of a substrate on which an etch process according to present methods has been performed.

FIG. 5A shows a TEM image of a wet recess etch process.

FIG. 5B shows a TEM image of a substrate on which an etch process according to disclosed methods has been formed.

### DETAILED DESCRIPTION

Methods are described for etching a higher quality sacrificial film in the presence of a lower quality non-sacrificial film. By using a dry etchant that is substantially insensitive to the quality of the dielectric layers being etched, sacrificial films of a first quality may be removed in the presence of non-sacrificial films of a second quality.

Methods of depositing and etching dielectric layers from a surface of a semiconductor substrate are disclosed. The methods may include depositing a first dielectric layer having a first wet etch rate in aqueous HF. The methods also may include depositing a second dielectric layer that may be initially flowable following deposition, and the second dielectric layer may have a second wet etch rate in aqueous HF that is higher than the first wet etch rate. The methods may further include etching the first and second dielectric layers with an etchant gas mixture, where the first and second dielectric layers have a ratio of etch rates that is closer to one than the ratio of the second wet etch rate to the first wet etch rate in aqueous HF.

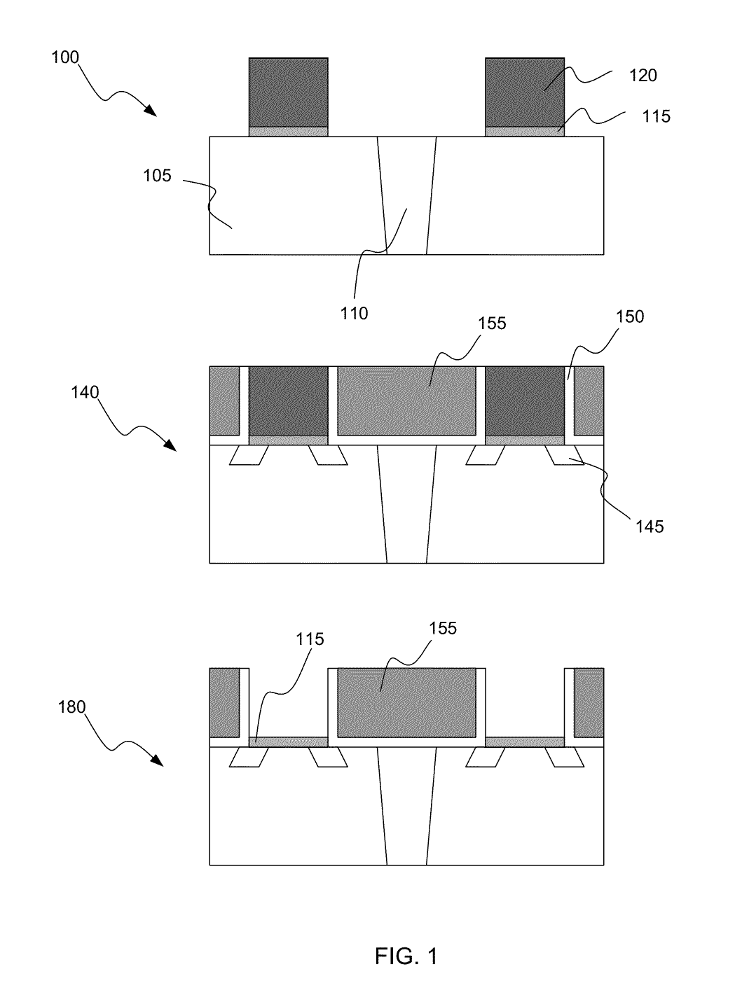

Referring to FIG. 1, a cross-sectional view of a semiconductor substrate is shown on which a dummy-gate removal process has been performed. For substrate 100, a silicon substrate 105 including a trench 110 is shown. First dielectric layer 115 is deposited to insulate the silicon substrate 105. The dielectric may be deposited as a continuous layer over the substrate. Dummy gate 120 is deposited over the first dielectric layer 115, followed by etching of both the dummy gate and the dielectric on which it lies to form islands or isolated gates. The dielectric may be an oxide, a nitride, or an oxynitride, and may be deposited by various means. The dielectric deposition may be a thermal oxide, or HDP-CVD, or may alternatively be an SACVD deposited dielectric. Alternatively, the dielectric may be deposited by a different technique that provide a relatively high-quality oxide for insulative purposes. The dummy gate may be any material that can be subsequently removed. For example, the dummy gate may be polysilicon, or some other metal, or oxide that is later removed in preparation for the replacement gate.

After the etching has been performed leaving the dummy gate structure, substrate 140 shows subsequent fabrication processes. Implant doping may be performed to create source/drains 145 in the substrate 105 under the dummy gates. Sidewall spacers 150 may be deposited to further isolate the substrate and gates that have been formed. The spacers may be nitride, in one example, and may be formed with a conformal growth technique, or may be blanket deposited and then etched to a determined thickness. A second dielectric layer 155 may be formed over the sidewall spacers 150, and may serve as an interlayer dielectric for integrated passive device scaling. The second dielectric may be deposited by a more flowable means, such as a flowable CVD or spin-on-glass, in order to provide better gap filling characteristics. Alternatively, second dielectric layer 155 may be deposited with an HDP-CVD, SACVD, or with other deposition techniques.

The second dielectric material 155 may be etched or subjected to a chemical mechanical planarization in order to reduce the material down to a level exposing the dummy gate. Once the dummy gate has been exposed, it may be removed using, for example, a polysilicon selective etch that removes only the polysilicon dummy gate as shown in substrate 180. Once the dummy gate has been removed, an etching technique can be performed in order to remove the first dielectric material 115. The first dielectric material 115 may be removed in a way that at least partially maintains the second dielectric material 155. On an exemplary substrate, the first dielectric material 115 is a higher quality thermal or HDP quality oxide, while the second dielectric 155 is a lower quality flowable dielectric. Hence, an etching technique removing the higher quality oxide while maintaining the lower quality oxide may be utilized.

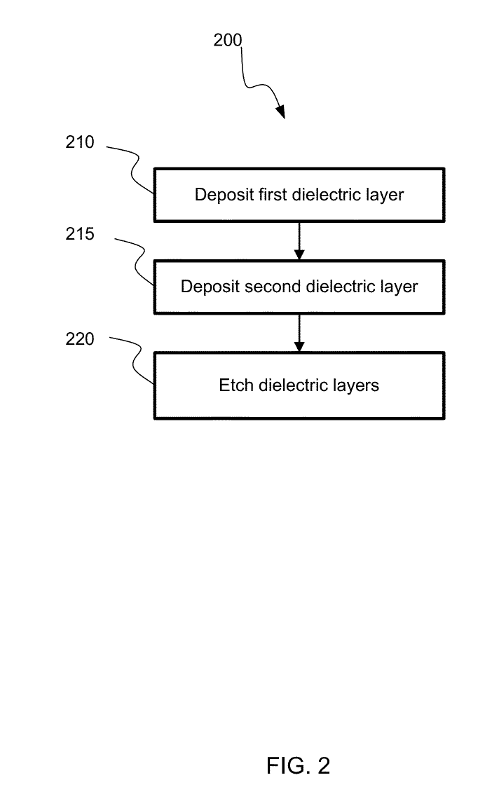

Referring to FIG. 2, which shows an etch process 200 according to disclosed methods, a first dielectric layer 210 may be formed on a semiconductor substrate. For example, the first dielectric layer may be formed in a gate last fabrication process, and may be used to create a protective layer on which other materials may be formed. The first dielectric layer may be formed by a less-flowable or non-flowable deposition technique, which may be a thermal oxide formation, HDP-CVD, or alternatively may be SACVD such as HARP, or PECVD such as plasma-enhanced TEOS and oxygen or TEOS and ozone. The first dielectric layer may include a silicon oxide, a silicon nitride, or a silicon oxy-nitride. The first dielectric layer may be formed within a trench on the substrate, or on the surface of the substrate. Further processing of the substrate may form other materials above and around the first dielectric layer such that the first dielectric layer is located within a feature on the substrate surface. As illustrated in FIG. 1, the dielectric layer may be first dielectric layer 115.

An HDP deposition produces a first dielectric layer with a first quality. Quality is a term used to describe compositions from a variety of aspects. The quality of an oxide may refer to density, purity, time to breakdown, etc. For example, a higher quality oxide is typically denser and has a higher breakdown voltage than a lower quality oxide. An HDP deposition may produce a dielectric layer or oxide of a higher quality than would a flowable deposition technique. The HDP film is produced by exciting the reactant gases at low pressure or even vacuum, often with radio frequency energy, which creates a plasma near the substrate surface. The plasma energy causes the elements to be highly reactive and produces high density and high quality films. In other embodiments a thermal process may be performed on the substrate to produce the first dielectric layer in which chemical reactions of the reactant gases are caused by heating the substrate up to a high temperature to induce the reaction and formation of the film.

After the first dielectric layer has been formed, intermediate steps may be performed. For example, in a replacement gate process, a layer of polysilicon or some other material to act as dummy gates may be formed above the first dielectric material. Etching of the dummy gates and first dielectric may be performed followed by the formation of spacers, made of a material such as nitride, which are placed between the dummy gates. For example, the processing described in reference to FIG. 1 may be performed.

A second dielectric layer may be deposited 215 on the semiconductor substrate. The second dielectric layer may be produced by a flowable deposition technique that may be spin-on-glass or flowable CVD, for example. Flowable CVD may be used to cover all of the previously formed layers with a dielectric material. For example, an interlayer dielectric may be formed to separate each of the deposited components from a subsequent layer of components when scaling to produce an integrated passive device. The dielectric layer deposited may be substantially conformal. Conformality refers to a deposition that produces a layer having uniform thickness on both horizontal and vertical surfaces, or a step coverage equal to about one.

A variety of methods may be used to deposit dielectric layers that are initially flowable after deposition. For example, a flowable CVD process may be used in which a silicon precursor is introduced to the substrate processing region housing the substrate. Another precursor is introduced after passing through a remote plasma region to create a radical precursor, such as a nitrogen precursor, which is then flowed into the substrate processing region and combined with the silicon precursor. With this technique, a silicon-containing precursor is not directly excited by an application of plasma power in the substrate processing region. Instead, plasma power is applied just to excite the radical precursor outside the substrate processing region. This arrangement results in the flowable deposition of a silicon-and-nitrogen-containing layer onto the substrate. The flowability of the film attenuates as the deposition proceeds and the flowability may be essentially removed during a curing operation.

The silicon-containing precursor may contain carbon and/or nitrogen in order to ensure flowability during dielectric layer formation. The silicon-containing precursor may be a carbon-free silicon-containing precursor which enables the dielectric layer to undergo less shrinkage during a curing process. The carbon-free silicon precursor may be, for example, a silicon-and-nitrogen precursor, a silicon-and-hydrogen precursor, or a silicon-nitrogen-and-hydrogen containing precursor, among other classes of silicon precursors. Specific examples of these precursors may include silyl-amines such as H₂N(SiH₃), HN(SiH₃)₂, and N(SiH₃)₃, among other silyl-amines. These silyl-amines may be mixed with additional gases that may act as carrier gases, reactive gases, or both. Examples of the these additional gases may include H₂, N₂, NH₃, He, and Ar, among other gases. Examples of carbon-free silicon precursors may also include silane (SiH₄) either alone or mixed with other silicon (e.g., N(SiH₃)₃), hydrogen (e.g., H₂), and/or nitrogen (e.g., N₂, NH₃) containing gases. The silicon-containing precursors may also include silicon compounds that have no carbon or nitrogen, such as silane, disilane, etc. If the deposited oxide film is a doped oxide film, dopant precursors may also be used such as TEB, TMB, B₂H₆, TEPO, PH₃, P₂H₆, and TMP, among other boron and phosphorous dopants.

Nitrogen may be included in either or both of the radical precursor and the silicon-containing precursor. When nitrogen is present in the radical precursor, it may be referred to as a radical-nitrogen precursor. The radical-nitrogen precursor includes plasma effluents created by exciting a more stable nitrogen-containing precursor in a plasma. For example, a relatively stable nitrogen-containing precursor containing NH₃ and/or hydrazine (N₂H₄) may be activated in a chamber plasma region or a remote plasma system (RPS) outside the processing chamber to form the radical-nitrogen precursor, which is then transported into a plasma-free substrate processing region. The stable nitrogen precursor may also be a mixture comprising NH₃ and N₂, NH₃ and H₂, NH₃ and N₂ and H₂, and N₂ and H₂, in different embodiments. Hydrazine may also be used in place of or in combination with NH₃ in the mixtures with N₂ and H₂. The flow rate of the stable nitrogen precursor alternatively may be greater than or about 200 sccm, greater than or about 300 sccm, greater than or about 500 sccm or greater than or about 700 sccm. Nitrogen-containing precursors may also include N₂O, NO, NO₂ and NH₄OH.

The radical-nitrogen precursor produced may include one or more of .N, .NH, .NH₂, etc., and may also be accompanied by ionized species formed in the plasma. The radical-nitrogen precursor may be alternatively generated in a section of the processing chamber partitioned from the substrate processing region where the precursors mix and react to deposit the silicon-and-nitrogen layer on a deposition substrate (i.e., a semiconductor wafer). The partition may be incorporated into a showerhead that supplies the reactants to the substrate processing region. The radical-nitrogen precursor may also be accompanied by a carrier gas such as argon, helium, etc. Oxygen may be simultaneously delivered into the remote plasma region (in the form of O₂ and/or O₃) to adjust the amount of oxygen content in the radical-nitrogen precursor and dielectric layer deposited with this technique. Alternatively, the oxygen delivered may bypass the remote plasma region and flow directly into the substrate processing region.

The flowability may be due, at least in part, to a significant hydrogen component in the deposited film. For example the deposited film may have a silazane-type, Si—NH—Si backbone (i.e., a Si—N—H film). Flowability may also result from short chained polymers of the silazane type. The nitrogen which allows the formation of short chained polymers and flowability may originate from either the radical precursor or the silicon-containing precursor. When both the silicon precursor and the radical-nitrogen precursor are carbon-free, the deposited silicon-and-nitrogen-containing film is also substantially carbon-free. Of course, “carbon-free” does not necessarily mean the film lacks even trace amounts of carbon. Carbon contaminants may be present in the precursor materials that find their way into the deposited silicon-and-nitrogen-containing film. The amount of these carbon impurities however are much less than would be found in a silicon precursor having a carbon moiety (e.g., TEOS, TMDSO, etc.).

The first and second dielectric layers may be deposited as both flowable or may both not be flowable. Alternatively, the dielectrics may be deposited by different mechanisms (e.g., the first is not flowable, and the second is flowable), but may have similar dielectric qualities depending on the reactants used. In other embodiments, the first and second dielectrics are deposited by the same mechanism, but have different qualities due to the use of different reactant species for the two dielectrics.

Flowable film growth may proceed while the substrate temperature is maintained at a relatively low temperature during deposition of the silicon-containing films. The flowable oxide film may be deposited on the substrate surface at a low temperature that is maintained by cooling the substrate during the deposition. The pedestal may include heating and/or cooling conduits that set the temperature of the pedestal and substrate between about −40° C. and about 1000° C., between about 100° C. and about 600° C., less than about 500° C. or at about 400° C. or less in different processes.

Subsequent to the second dielectric layer formation, intermediate steps may be performed for different processes. For example, chemical mechanical planarization (“CMP”) may be performed to remove excess amounts of the second dielectric layer. The CMP may be performed to expose a separate layer including, for example, a polysilicon dummy gate that had been previously deposited. Additionally, a polysilicon-selective wet etch process may be performed to remove the dummy gate that had been previously deposited. A polysilicon-selective etch refers to an etching process that preferentially removes polysilicon in the presence of other materials. The process may be due to chemical reactions that occur with the polysilicon instead of the other materials, or from the additional formation of a sacrificial layer or photo-resist layer that is deposited to protect the other materials from the etching of the polysilicon. The polysilicon or other material may be removed to expose the first dielectric layer, thereby allowing both the first dielectric layer and second dielectric layer to be exposed.

After the flowable dielectric has been deposited on the substrate and any intermediate steps have been performed, an etching process may be performed in order to remove excess dielectric in preparation for subsequent integrated passive device manufacturing steps. A dry etchant gas may be used to etch 220 the dielectric layers. The etchant may remove a portion of both the first dielectric layer and the second dielectric layer. The etchant may include a fluorine-containing compound, such as nitrogen trifluoride, and ammonia. The etchant gases react with the dielectric layers to produce solid byproducts that sublimate when the temperature of the substrate is raised above the sublimation temperature, thereby removing the excess dielectric. Prior to flowing into the process chamber, the dry etchant gases may flow through a remote plasma system in which they are radicalized prior to entering the reaction region. The etch rate ratio for removing the first dielectric liner layer to removing the second dielectric layer may be about 1:2, or in other embodiments may be about 1:1.5, 1:1.3, 1:1.2, 1:1.1, 1:1.05, 1:1.01, or about 1:1. When the etch rate ratio is equal to 1:1 the first and second dielectric layers are removed at the same rate.

The first dielectric layer may be a thin protective layer over the substrate and may be sacrificial. The first dielectric layer may be completely removed, or substantially removed with the etching process in order to prepare the substrate for subsequent processes that may include, for example, metal gate deposition and layering. However, etching of the first dielectric layer may also expose the second dielectric layer to the etchant gas. If the second dielectric layer is an interlayer dielectric, for example, the second layer may be non-sacrificial and its maintenance during removal of the first dielectric layer may be sought to protect against dopant or charge diffusion between layers. The etching may be performed for a length of time that allows for the removal of enough dielectric material to remove the first dielectric layer, and the time required may be dependent on the thickness of the first dielectric layer.

The second dielectric layer may be of about the same or a greater thickness than the first dielectric layer. Additionally, the second dielectric layer may be of about the same, or of a higher or lower quality than the first dielectric layer. If the second dielectric layer is of a higher quality than the first dielectric layer, for example, then a more sensitive or selective etching process may be used because the etching may remove the sacrificial first dielectric layer at a faster rate than the non-sacrificial second dielectric layer. Alternatively, if the second dielectric layer is of a lower quality than the first dielectric layer, then an etching process that is less sensitive or insensitive to oxide quality may be used. An etching process that is substantially insensitive to oxide quality may be capable of removing oxides of different qualities at substantially the same rate.

Etching with a dry etchant gas may be performed to remove less than about 100 angstroms of material in order to completely remove the first dielectric layer. Depending on the thickness of the first dielectric layer, the etching process may remove about 75 angstroms or less of dielectric material, about 50 angstroms or less, about 40 angstroms or less, about 30 angstroms or less, about 25 angstroms or less, about 20 angstroms or less, about 15 angstroms or less, about 10 angstroms or less, about 5 angstroms or less, etc. The dry etchant gas may remove substantially all or all of the first dielectric layer without completely removing the second dielectric layer. This removal may occur despite the second dielectric layer being of a lower quality than the first dielectric layer. After the removal of the first dielectric layer, subsequent fabrication steps may be performed including metallization and circuit scaling.

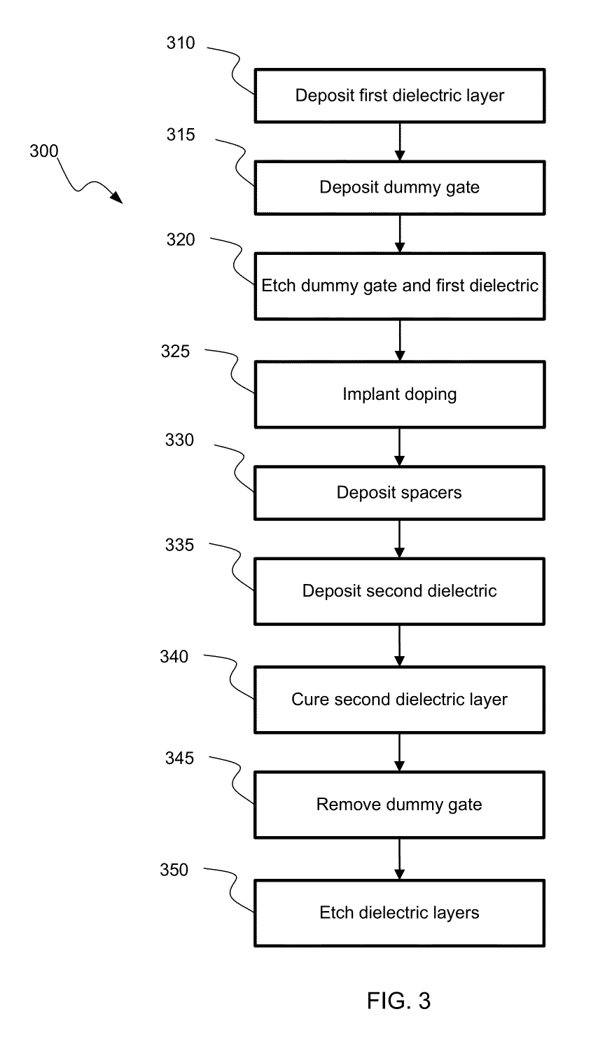

Referring now to FIG. 3, a method 300 of removing a dielectric material on a surface of a semiconductor substrate is described. The methods may be utilized for gate last processing and may include depositing 310 a first dielectric material on the substrate to produce a dielectric layer of a first quality that has a first wet etch rate in aqueous HF. The wet etch rate in HF may be proportional to the quality of the material being deposited. For example, if the dielectric layer is of a high quality, then the etch rate in aqueous HF would be slower than if the dielectric layer is of a lower quality. The first dielectric layer may be any type or quality of material, and in one example, the first dielectric layer is an oxide material deposited by HDP CVD. Alternatively, the first dielectric layer may be a nitride or other material that may cover the substrate. The first dielectric layer may be a thin layer used to protect an underlying substrate, and may be less than about 50 angstrom in thickness. The first dielectric layer may be removed while a second material layer is at least partially maintained during the removal. The second dielectric material may be partially removed during the removal of the first dielectric layer, but the amount of removal of the second material may be limited by the specific removal process.

After the first dielectric material has been deposited, additional manufacturing processes may occur including additional deposition or growth layers, material removal, material doping, etc. A gate last process may be performed in which a layer of polysilicon or some other material is deposited 315 above the first dielectric layer. A subsequent etching 320 may create islands of polysilicon or dummy gates. Trenches may be formed and filled with a dielectric material and implant doping may be performed 325 before or after any of the identified processes, including deposition of the first dielectric material. Sidewall spacers of nitride or some other material may be deposited 330 between the dummy gates prior to a deposition of an interlayer dielectric. The spacers may be a nitride, for example, and may be etched to a determined thickness prior to the deposition of the interlayer dielectric.

A second dielectric material may also be deposited 335, and the second dielectric material may be initially flowable following deposition. The second dielectric material may fill between and above any dummy gates or spacers that may have been deposited. By depositing the second dielectric material such that it is initially flowable following deposition, the flowability may help to prevent the development or voids, seams, or other defects. The flowable deposition may be performed by spin-on-glass, flowable CVD, or other methods that produce a dielectric material that is initially flowable after deposition. Alternatively, the second dielectric material may be deposited by non-flowable techniques that may produce a dielectric of a higher quality. The second dielectric material may be an oxide, nitride, or other material of a second quality that has a second wet etch rate in aqueous HF, and this second wet etch rate may be greater than the first wet etch rate. Depending on the film qualities of the first and second dielectric materials, the second dielectric material may have a second wet etch rate that is about twice the rate or more of the first wet etch rate, or about four, about six, about eight, about ten, about twelve, about twenty, about thirty, or about forty or more times the first wet etch rate.

The second dielectric material may be cured 340 following deposition in order to create a dielectric layer with improved film quality. Curing may be carried out in oxidative environments like steam, inert environments such as nitrogen, or other environments in various embodiments. The flowability of the film attenuates as the deposition proceeds and the flowability is essentially removed during the curing operation. The curing operation may involve converting a silicon-and-nitrogen containing layer to silicon oxide. Curing may involve raising the patterned substrate temperature and exposing the dielectric material to an oxygen containing environment. The curing may be an anneal, and may be performed at temperatures below about 1000° C. The curing may instead occur below about 800° C., 600° C., 500° C., 400° C., 300° C., 200° C., or below about 100° C. or less.

An anneal may improve the dielectric film characteristics including hardness, quality (e.g., improved density), uniformity, mobility, charge-to-breakdown, etc. A post-oxidation anneal may densify the film and remove some of the defects that may have been incorporated during deposition. Utilizing a flowable deposition technique may reduce the thermal budget of the manufacturing process in that if the temperature is raised above a threshold, reflow of the dielectric may occur. Similarly, when performing certain types of fabrication such as gate last, elevated temperatures may also allow dopant diffusion to occur. Therefore, the curing may be performed below a threshold temperature, which in some cases may be below about 600° C., about 500° C., 400° C., 300° C., 200° C., or below about 100° C. or less. Additionally, an etching or polishing process such as chemical mechanical planarization may be performed in order to reduce the interlayer dielectric to a level that exposes the dummy gate.

After the second dielectric layer has been formed, other manufacturing processes may be performed. Exemplary processes may include CMP to remove excess dielectric material that was deposited, and/or a selective etching process 345 in order to remove dummy gates that were previously deposited. The etching may be a polysilicon selective wet etch, for example, and may remove the dummy gate down to the level of the first dielectric material. Additionally, other etching and deposition steps may be performed along with material doping, or other processes used in microfabrication.

An etching process 350 may be performed after curing the second dielectric layer. The etching may include exposing the substrate to a dry etchant gas that removes at least a portion of the first dielectric layer. The dry etchant may be a mixture of gases that includes a fluorine-containing compound, such as nitrogen trifluoride, as well as ammonia. The dry etchant may additionally include other gases such as helium or other inert gases. The gases may be flowed separately into the processing chamber in which the substrate resides, and the dry etchant gas may also be excited by a remote plasma source prior to its being flowed into the process chamber. The dry etchant gas mixture may remove a portion of the second dielectric along with the first dielectric layer being removed.

The first dielectric may be a sacrificial layer, and the second dielectric layer may be non-sacrificial. The dry etchant gas may remove the sacrificial and non-sacrificial dielectric layers at substantially similar rates, and may be substantially insensitive to the quality of the dielectric layers. For example, the first dielectric layer may be a higher quality HDP oxide, and the second dielectric layer may be a lower quality flowable oxide. While a wet etch using aqueous HF may remove the lower quality second dielectric layer more than about twice as fast as the higher quality first dielectric layer, the dry etchant gas may not.

The dry etchant gas may remove both the higher quality and the lower quality dielectric layers at similar rates in order to maintain at least a portion of the second dielectric layer while removing the first dielectric layer. The first and second dielectric layers may have a ratio of etch rates with the dry etchant gas mixture that is closer to one than the ratio of the second etch rate to the first wet etch rate in aqueous HF. The second dielectric layer may be used as an interlayer dielectric to help prevent dopant migration, among other protective uses, in one example. Advantageously, by limiting the removal of this layer while removing a higher quality sacrificial layer, diffusion, charge transfer, and other issues may be prevented during scaling of a semiconductor or integrated passive device.

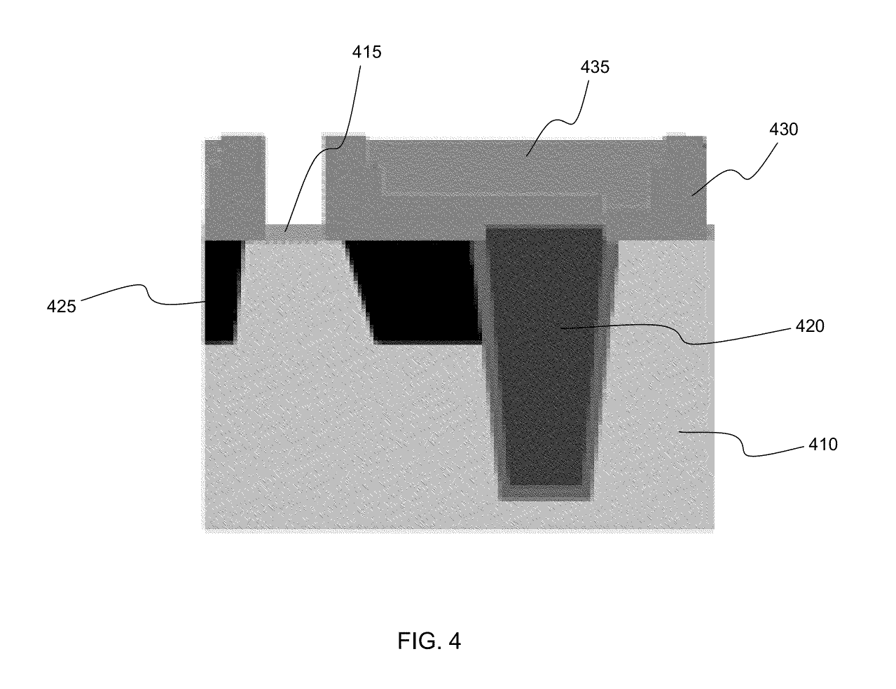

Turning to FIG. 4, a cross-sectional view is shown of a substrate 410 on which an etch process according to present methods has been performed. An HDP quality dielectric material 415 is deposited on the substrate 410 prior to deposition of dummy gates (not shown). Etching, shallow trench isolation 420, and implant doping 425 are conducted along with spacer formation 430. The shallow trench isolation 420, may alternatively be performed prior to the deposition of the HDP quality dielectric material and dummy gates. A second dielectric layer, or interlayer dielectric, 435 is deposited over the substrate, which may be initially flowable after deposition, and CMP is performed to remove excess dielectric and expose the dummy gates. A polysilicon selective wet etch is performed to remove the dummy gates thereby exposing the HDP quality dielectric material 415. A dry etchant gas mixture of nitrogen trifluoride, ammonia, and helium is exposed to the substrate to remove the HDP quality dielectric material 415. The gas may flow through a remote plasma chamber prior to flowing into the reaction region. An amount of the interlayer dielectric 435 may be removed during the removal of the HDP quality dielectric material 415. However, despite that the interlayer dielectric 435 may be of a lower quality than the HDP quality dielectric material 415, the dry etchant gas mixture may remove the layers at substantially similar rates. Thus, the amount of interlayer dielectric material 435 that is removed is limited during the removal of the HDP quality dielectric material.

### EXAMPLES

Comparative examples were made between etch selectivity using a dry etchant gas mixture. The etches were conducted on substrates containing oxides deposited by HDP CVD as well as a flowable CVD. The flowable oxide was cured with an anneal at 400° C. prior to etching. The oxides were exposed to a dry etchant gas mixture containing nitrogen trifluoride and ammonia for a period of thirteen seconds. As can be seen in Table I below, the dry etchant gas mixture removes only slightly more of the flowable oxide as compared to the HDP quality oxide, which indicates that the dry etchant gas is substantially insensitive to oxide quality:

TABLE I
ETCH DEPTH OF DRY ETCHANT GAS

| | Etch Depth | Selectivity with |
|---|---|---|
| | (angstrom) | respect to HDP oxide |
| HDP Oxide | 132 | 1.0000 |
| Flowable Oxide | 133 | 1.0076 |

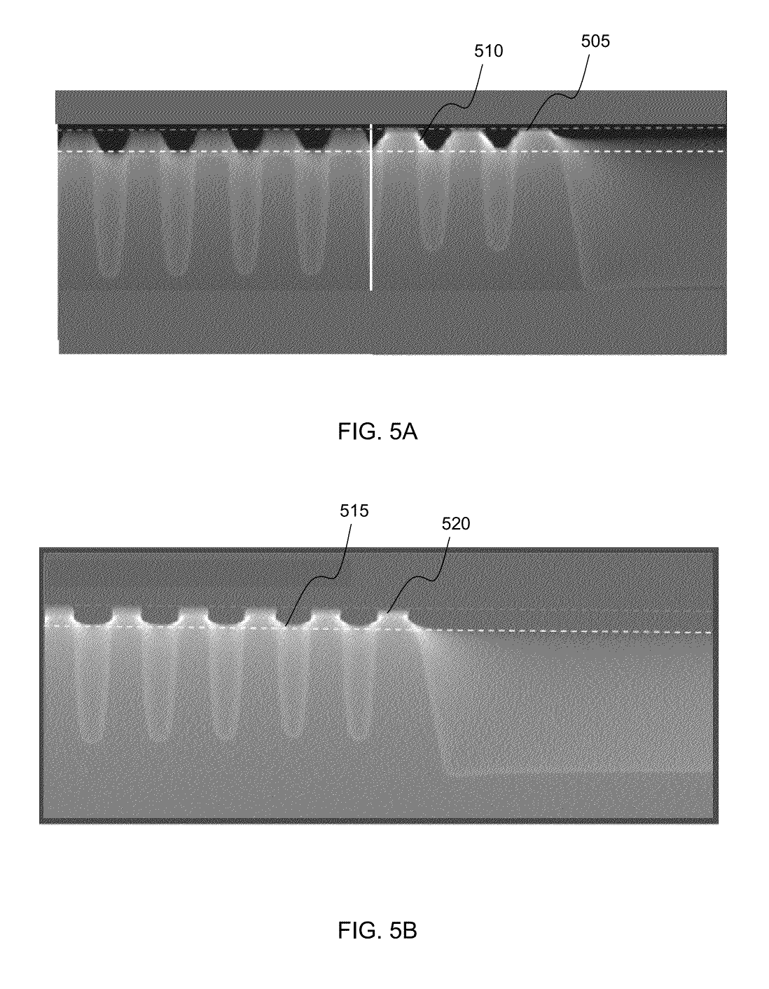

FIG. 5A is an SEM image showing etch depth in trenches and open fields using an aqueous HF etchant. The HF is sensitive to oxide quality, and thus differences in oxide quality are reflected in different etch depths. Open fields 505 are not of a uniform height, and trenches 510 show inconsistent amounts of oxide removal. FIG. 5B, however, shows an SEM image showing etch depth in trenches and open fields using a dry etchant gas mixture. The dry etchant gas mixture includes nitrogen trifluoride and ammonia. The dry etchant gas mixture is substantially insensitive to oxide quality, and recess amounts for both the open fields 520 and the trenches 515 are substantially similar and uniform.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the disclosed embodiments. Additionally, a number of well known processes and elements have not been described in order to avoid unnecessarily obscuring the present invention. Accordingly, the above description should not be taken as limiting the scope of the invention.

It is noted that individual embodiments may be described as a process which is depicted as a flowchart, a flow diagram, or a block diagram. Although a flowchart may describe the method as a sequential process, many of the operations may be performed in parallel or concurrently. In addition, the order of the operations may be rearranged. A process may be terminated when its operations are completed, but could have additional steps not discussed or included in a figure. Furthermore, not all operations in any particularly described process may occur in all embodiments. A process may correspond to a method, a function, a procedure, a subroutine, a subprogram, etc. When a process corresponds to a function, its termination corresponds to a return of the function to the calling function or the main function.

Where a range of values is provided, it is understood that each intervening value, to the smallest fraction of the unit of the lower limit, unless the context clearly dictates otherwise, between the upper and lower limits of that range is also specifically disclosed. Each smaller range between any stated value or intervening value in a stated range and any other stated or intervening value in that stated range is encompassed. The upper and lower limits of those smaller ranges may independently be included or excluded in the range, and each range where either, neither, or both limits are included in the smaller ranges is also encompassed within the invention, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a dielectric material” includes a plurality of such materials, and reference to “the deposition” includes reference to one or more depositions and equivalents thereof known to those skilled in the art, and so forth.

Also, the words “comprise”, “comprising”, “include”, “including”, and “includes”, when used in this specification and in the following claims, are intended to specify the presence of stated features, integers, components, or steps, but they do not preclude the presence or addition of one or more other features, integers, components, steps, acts, or groups.

What is claimed is:

1. A method of depositing and etching dielectric layers from a surface of a semiconductor substrate, the method comprising:
depositing a first dielectric layer with a first wet etch rate in aqueous HF;
depositing a second dielectric layer, wherein the second dielectric layer is initially flowable following the deposition, and wherein the second dielectric layer has a second wet etch rate in aqueous HF that is higher than the first wet etch rate; and
etching the first and second dielectric layers with an etchant gas mixture comprising a fluorine-containing gas and ammonia, wherein the first and second dielectric layers have a ratio of etch rates with the etchant gas mixture that is closer to 1 than the ratio of the second wet etch rate to the first wet etch rate in aqueous HF.

2. The method of claim 1, wherein the etchant gas mixture is a dry etchant gas mixture comprising plasma effluents.

3. The method of claim 1, wherein at least one of the first and second dielectric layers comprises an oxide.

4. The method of claim 1, wherein the first dielectric layer is deposited by either a thermal deposition process or a high-density plasma deposition process.

5. The method of claim 4, wherein the first dielectric layer is deposited by a high-density plasma deposition process.

6. The method of claim 1, wherein the second dielectric layer is deposited by either spin-on-glass or flowable CVD.

7. The method of claim 6, wherein the second dielectric layer is deposited by flowable CVD.

8. The method of claim 1, further comprising curing the second dielectric layer after depositing it.

9. The method of claim 8, wherein the second dielectric layer is deposited, cured, and etched at a temperature of about 400° C. or less.

10. The method of claim 1, wherein the ratio of etch rates with the etchant gas mixture is below about 1.1.

11. A method of removing a dielectric material on a surface of a semiconductor substrate in a replacement metal gate semiconductor process, the method comprising:
depositing a first dielectric material on the substrate to produce a dielectric layer of a first quality that has a first wet etch rate in aqueous HF;
depositing a second dielectric material, wherein the second dielectric is initially flowable following the deposition;
curing the second dielectric material to produce a second dielectric layer of a second quality that has a second wet etch rate in aqueous HF that is greater than the first wet etch rate;
etching the first and second dielectric layers with a dry etchant gas mixture, wherein the first and second dielectric layers have a ratio of etch rates with the dry etchant gas mixture that is closer to 1 than the ratio of the second wet etch rate to the first wet etch rate in aqueous HF.

12. The method of claim 11, wherein the dry etchant gas mixture comprises plasma effluents of a fluorine-containing gas and ammonia.

13. The method of claim 12, wherein the fluorine containing gas is nitrogen trifluoride.

14. The method of claim 11, wherein the second dielectric layer is deposited, cured, and etched at a temperature of about 400° C. or less.

15. The method of claim 11, wherein the dry etchant gas is substantially insensitive to the quality of the dielectric layer being etched such that the ratio of the etch rate with the dry etchant gas of the second dielectric to the etch rate with the dry etchant gas of the first dielectric layer is below about 1.1.

16. The method of claim 1, wherein the first dielectric layer is deposited by either a thermal deposition process or a high-density plasma deposition process.

17. The method of claim 4, wherein the first dielectric layer is deposited by a high-density plasma deposition process.

18. The method of claim 1, wherein the second dielectric layer is deposited by either spin-on-glass or flowable CVD.

19. The method of claim 6, wherein the second dielectric layer is deposited by flowable CVD.
